(19) United States
(12) Patent Application Publication
(10) Pub. No.: US 2023/0026972 A1
(43) Pub. Date: Jan. 26, 2023

(54) SEMICONDUCTOR PACKAGE AND METHOD OF FABRICATING THE SAME

(71) Applicant: Samsung Electronics Co., Ltd., Suwon-si (KR)

(72) Inventors: Yeonho JANG, Cheonan-si (KR); Dongkyu KIM, Anyang-si (KR); Shang-Hoon SEO, Suwon-si (KR); Jaegwon JANG, Hwaseong-si (KR)

(73) Assignee: Samsung Electronics Co., Ltd., Suwon-si (KR)

(21) Appl. No.: 17/700,818

(22) Filed: Mar. 22, 2022

(30) Foreign Application Priority Data
Jul. 14, 2021 (KR) 10-2021-0092187

(51) Int. Cl. H01L 23/538; H01L 23/31; H01L 23/485; H01L 23/498; H01L 23/00

(52) U.S. Cl. CPC H01L 23/5389; H01L 23/3128; H01L 23/485; H01L 23/49816; H01L 24/13; H01L 24/19; H01L 24/20; H01L 2924/15311; H01L 2224/12105; H01L 2224/04105; H01L 2224/02379; H01L 2224/02373

(57) ABSTRACT

Disclosed are semiconductor packages and their fabricating methods. The semiconductor package includes a lower structure and an upper redistribution layer. The lower structure includes a first bump layer, a lower redistribution layer, a semiconductor chip, a molding layer, a conductive pillar, and an under pad layer. The upper redistribution layer includes a second bump layer and second redistribution layers. The first redistribution layer includes a lower redistribution pattern including a first line part and a first via part. A width of the first via part increases in a direction toward the first line part from a bottom surface of the first via part. The second redistribution layer includes an upper redistribution pattern including a second line part and the second via part. A width of the second via part increases in a direction toward the second line part from a top surface of the second via part.

### CROSS-REFERENCE TO RELATED APPLICATION

This U.S. nonprovisional application claims priority under 35 U.S.C. § 119 to Korean Patent Application No. 10-2021-0092187 filed on Jul. 14, 2021 in the Korean Intellectual Property Office, the disclosure of which is hereby incorporated by reference in its entirety.

### BACKGROUND

The present inventive concepts relate to semiconductor packages and/or methods of fabricating the same, and more particularly, to fan-out packages and/or methods of fabricating the same.

In the semiconductor industry, high capacity, thinness, and small size of semiconductor devices and electronic products using the same have been demanded and thus various package techniques have been suggested. A semiconductor package is provided to implement an integrated circuit chip to qualify for use in electronic products. A semiconductor package is typically configured such that a semiconductor chip is mounted on a printed circuit board (PCB) and bonding wires or bumps are used to electrically connect the semiconductor chip to the printed circuit board. With the development of the electronics industry, electronic products have increasingly demands for high performance, high speed, and compact size.

### SUMMARY

Some example embodiments of the present inventive concepts provide semiconductor packages and/or methods of fabricating the same, which solves problems of process yield reduction caused by the fact that a step of forming a front redistribution layer, a step of assembling, and a step of forming a back redistribution layer are sequentially performed in semiconductor package fabrication.

According to some example embodiments of the present inventive concepts, a semiconductor package includes a lower structure and an upper redistribution layer on the lower structure. The lower structure includes a first bump layer including a bump pattern, a lower redistribution layer including a plurality of first redistribution layers stacked on the first bump layer, a semiconductor chip on the lower redistribution layer; a molding layer on the lower redistribution layer and covering the semiconductor chip, a conductive pillar on the lower redistribution layer and penetrating the molding layer, and an under pad layer on the molding layer and including an under pad. The upper redistribution layer includes a second bump layer including an upper bump pattern and a plurality of second redistribution layers stacked between the second bump layer and the under pad layer. Each of the plurality of first redistribution layers includes a lower redistribution pattern. The lower redistribution pattern includes a first line part and a first via part. A width of the first via part may increase in a first vertical direction toward the first line part from a bottom surface of the first via part. Each of the plurality of second redistribution layers includes an upper redistribution pattern. The upper redistribution pattern includes a second line part and the second via part. The second via part is on the second line part. A width of the second via part increases in a second vertical direction toward the second line part from a top surface of the second via part.

According to some example embodiments of the present inventive concepts, a method of fabricating a semiconductor package includes forming a lower structure on a first carrier, the forming the lower structure including forming on the first carrier a first bump layer that includes a bump pattern, forming a lower redistribution layer on the first bump layer, forming on the lower redistribution layer a conductive pillar that extends vertically, and mounting a semiconductor chip on the lower redistribution layer, forming on the lower redistribution layer a molding layer, the molding layer covering the semiconductor chip and the conductive pillar and exposing a top surface of the conductive pillar, forming on the molding layer an under pad layer that includes an under pad in contact with the top surface of the conductive pillar, forming an upper redistribution layer on a second carrier, the upper redistribution layer including an upper bonding pad at an uppermost position of the upper redistribution layer, bonding the lower structure and the upper redistribution layer to connect the under pad and the upper bonding pad to each other, and removing the first carrier and the second carrier.

### BRIEF DESCRIPTION OF THE DRAWINGS

FIG. 1 illustrates a cross-sectional view showing a semiconductor package according to some example embodiments of the present inventive concepts.

FIG. 2 illustrates an enlarged view showing section A of FIG. 1.

FIG. 3 illustrates an enlarged view showing section B of FIG. 1.

FIG. 4 illustrates an enlarged view showing section C of FIG. 1.

FIG. 5 illustrates a cross-sectional view showing the formation of a redistribution layer and a conductive pillar.

FIG. 6 illustrates a cross-sectional view showing the mounting of a die on a redistribution layer.

FIG. 7 illustrates a cross-sectional view showing the formation of a molding layer on a redistribution layer.

FIG. 8 illustrates a cross-sectional view showing the formation of an under pad layer on a molding layer and a conductive pillar.

FIG. 9 illustrates a cross-sectional view showing the formation of a second bump layer and first to third upper redistribution layers.

FIG. 10 illustrates a cross-sectional view showing the formation of a second dielectric layer on a third redistribution layer.

FIG. 11 illustrates a cross-sectional view showing the alignment of a first carrier and a second carrier to face each other.

FIG. 12 illustrates a cross-sectional view showing the separation a first carrier and the bonding of an external terminal after the bonding of a lower structure to an upper redistribution layer.

FIG. 13 illustrates a cross-sectional view showing the separation of a second carrier.

FIG. 14 illustrates a cross-sectional view showing the formation of a first dielectric layer on a molding layer and a conductive pillar.

FIG. 15 illustrates a cross-sectional view showing the formation of an opening in a first dielectric layer.

FIG. 16 illustrates a cross-sectional view showing the formation of a seed pad layer on an opening and a first dielectric layer.

FIG. 17 illustrates a cross-sectional view showing the formation of a conductive layer on a seed pad layer.

FIGS. 18A to 18C illustrate cross-sectional views showing some example embodiments of an under pad.

FIG. 19 illustrates a cross-sectional view showing a second dielectric layer and an upper bonding pad that protrudes onto the second dielectric layer.

FIG. 20 illustrates a cross-sectional view showing the formation of a second dielectric film.

FIG. 21 illustrates a cross-sectional view showing the polishing of a second dielectric film.

FIG. 22 illustrates a cross-sectional view showing a semiconductor package according to some example embodiments of the present inventive concepts.

### DETAILED DESCRIPTION

In order to sufficiently understand the configuration and effects of the present inventive concepts, some example embodiments of the present inventive concepts will be described with reference to the accompanying drawings.

As used herein, the term “and/or” includes any and all combinations of one or more of the associated listed items. Expressions such as “at least one of,” when preceding a list of elements, modify the entire list of elements and do not modify the individual elements of the list. Thus, for example, both “at least one of A, B, or C” and “A, B, and/or C” means either A, B, C or any combination thereof.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

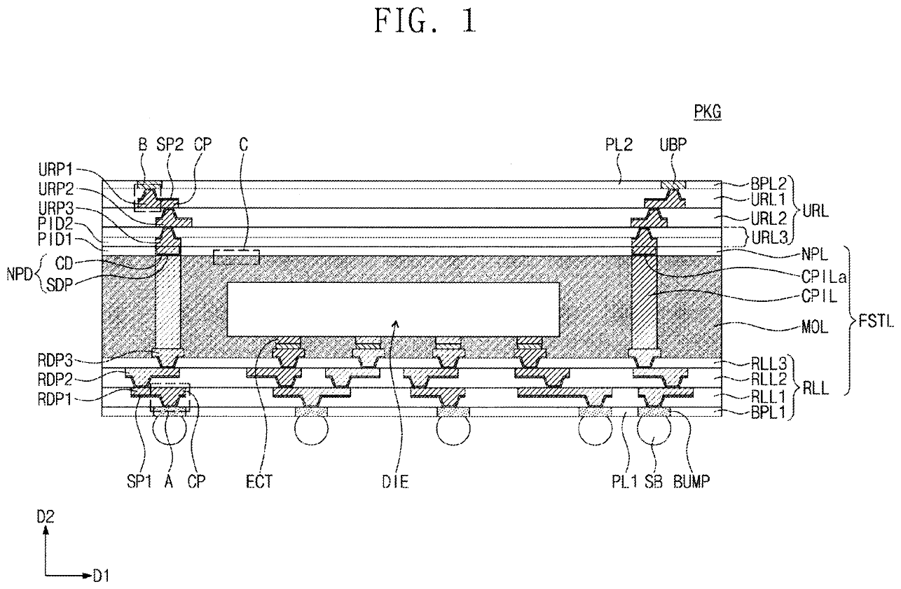

The following will describe in detail some example embodiments of the present inventive concepts with reference to FIGS. 1 to 22.

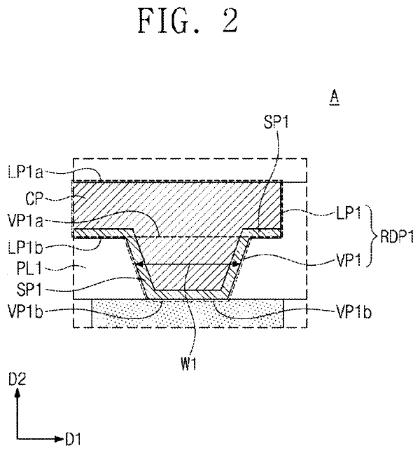

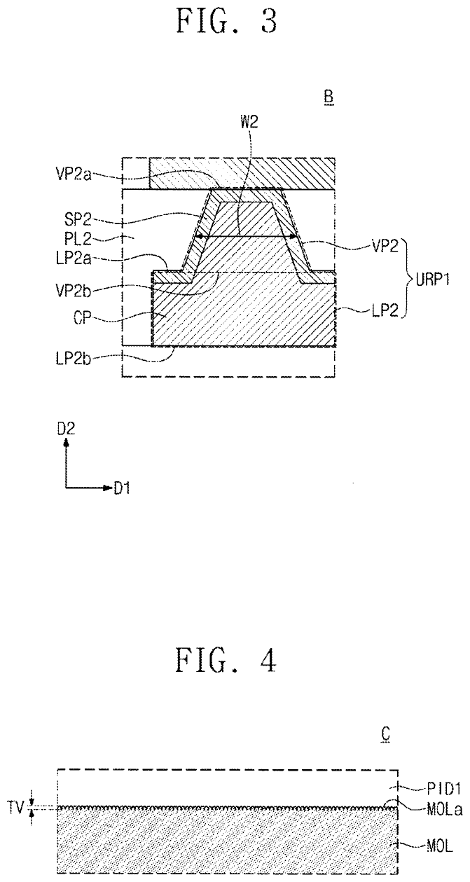

FIG. 1 illustrates a cross-sectional view showing a semiconductor package according to some example embodiments of the present inventive concepts. FIG. 2 illustrates an enlarged view showing section A of FIG. 1. FIG. 3 illustrates an enlarged view showing section B of FIG. 1. FIG. 4 illustrates an enlarged view showing section C of FIG. 1.

Referring to FIGS. 1 to 4, a semiconductor package PKG according to some example embodiments may include a lower structure FSTL, an upper redistribution layer URL, and external terminals SB. The lower structure FSTL may include a lower redistribution layer RLL, a die DIE, a molding layer MOL, conductive pillars CPIL, and an under pad layer NPL. The lower structure FSTL may include a front redistribution layer of the semiconductor package PKG.

The lower redistribution layer RLL may include a first bump layer BPL1, a first lower redistribution layer RLL1, a second lower redistribution layer RLL2, and a third lower redistribution layer RLL3 that are sequentially stacked. The first bump layer BPL1 may include first bump patterns BUMP. The first lower redistribution layer RLL1 may include first lower redistribution patterns RDP1. The second lower redistribution layer RLL2 may include second lower redistribution patterns RDP2. The third lower redistribution layer RLL3 may include lower bonding pads RDP3. Each of the lower bonding pads RDP3 may protrude upwardly beyond the third lower redistribution layer RLL3. Each of the first and second lower redistribution patterns RDP1, RDP2, and the lower bonding pads RDP3 may include a first seed pattern SP1 and a conductive pattern CP on the first seed pattern SP1. The first seed patterns SP1 may include a conductive seed material. The conductive seed material may include one or more of copper, titanium, and any alloy thereof.

The present inventive concepts are not limited thereto, and the lower redistribution layer RLL may have no limitation imposed on the number of redistribution layers and the number of redistribution patterns.

Referring to FIG. 2, among the first and second lower redistribution patterns RDP1 and RDP2 and the lower bonding pads RDP3 of the lower redistribution layer RLL, the first lower redistribution pattern RDP1 is representatively illustrated. The first lower redistribution pattern RDP1 may include a first line part LP1 and a first via part VP1.

The first via part VP1 may include a portion of the first seed pattern SP1 and a portion of the conductive pattern CP on the first seed pattern SP1. The first line part LP1 may be provided on the first via part VP1. The first line part LP1 may have a top surface LP1a in partial contact with a first dielectric layer, another redistribution pattern, or a lower bonding pad. The first line part LP1 may have a bottom surface LP1b, which is connected to a top surface VP1a of the first via part VP1. The first via part VP1 may be provided between the first line part LP1 and a lower bump pattern (or another redistribution pattern). The first line part LP1 may be electrically connected through the first via part VP1 to the lower bump pattern (or another redistribution pattern).

The first via part VP1 may have a first width W1. The first width W1 may be defined to refer to a length between one and opposite lateral surfaces of the first via part VP1. The first width W1 may increase in a direction from a bottom surface VP1b toward the top surface VP1a of the first via part VP1, or in a second direction D2. A width at the bottom surface VP1b of the first via part VP1 may be less than that at the top surface VP1a of the first via part VP1.

The lower redistribution layer RLL may include a plurality of first dielectric layers PL1. The first dielectric layers PL1 may include an organic material, such as a photo-imagable dielectric (PID) material. The photo-imagable dielectric material may be a polymer. The photo-imagable dielectric material may include, for example, one or more of photosensitive polyimide, polybenzoxazole, phenolic polymers, and benzocyclobutene polymers. The number of stacked first dielectric layers PL1 may be variously changed. The plurality of first dielectric layers PL1 may include the same material. No distinct interface may be provided between neighboring first dielectric layers PL1.

A plurality of lower bump patterns BUMP may be provided below the first lower redistribution layer RLL1. The lower bump patterns BUMP may be connected to corresponding ones of the first lower redistribution patterns RDP1. A plurality of external terminals SB may be provided below corresponding ones of the lower bump patterns BUMP. The lower bump pattern BUMP may lie between and connect the external terminal SB and the first lower redistribution pattern RDP1. For example, the external terminal SB may be a solder ball. The external terminal SB may include, for example, tin, bismuth, lead, silver, or any alloy thereof.

The die DIE may be provided on the lower redistribution layer RLL. The die DIE may be a semiconductor chip. For example, the semiconductor chip may include one of a logic chip, a memory chip, and a power management chip. The semiconductor chip may include an applicant specific integrated circuit (ASIC) chip or an application processor (AP) chip. The ASIC chip may include an application specific integrated circuit (ASIC). In some example embodiments, the die DIE may include a central processing unit (CPU) or a graphic processing unit (GPU).

The die DIE may have a top surface and a bottom surface that are opposite to each other. The bottom surface of the die DIE may be directed toward the lower redistribution layer RLL and may be an active surface. The top surface of the die DIE may be an inactive surface. For example, the die DIE may include a semiconductor substrate, integrated circuits, and external connection members ECT. The semiconductor substrate may include silicon, germanium, or silicon-germanium. The semiconductor substrate may be a silicon wafer. The integrated circuits may be adjacent to the bottom surface of the die DIE. The external connection members ECT may be coupled to the integrated circuits. The phrase “a certain component is electrically connected to the die DIE” may mean “a certain component is electrically connected through the external connection members ECT of the die DIE to the integrated circuits of the die DIE.”

Differently from that shown, an additional die (or a semiconductor chip) may be mounted on the lower redistribution layer RLL. For example, a plurality of dies DIE may be mounted on the lower redistribution layer RLL.

The external connection members ECT of the die DIE may be disposed on corresponding ones of the lower bonding pads RDP3 of the lower redistribution layer RLL. As the external connection members ECT are connected to corresponding ones of the lower bonding pads RDP3, the die DIE and the lower redistribution layer RLL may be electrically connected to each other. For example, the external connection members ECT may include micro-bumps.

At least one conductive pillar CPIL may be mounted on the lower redistribution layer RLL. The conductive pillar CPIL may be provided on an edge region of the lower redistribution layer RLL. The conductive pillar CPIL may be horizontally spaced apart from the die DIE. The conductive pillar CPIL may extend in a direction perpendicular to a bottom surface thereof, or in the second direction D2. As discussed below, the conductive pillar CPIL may penetrate the molding layer MOL.

The conductive pillar CPIL may be connected to the lower bonding pad RDP3 that corresponds thereto. In this case, the conductive pillar CPIL may be electrically connected to the lower redistribution layer RLL. For example, the conductive pillar CPIL may be electrically connected through the lower redistribution layer RLL to the die DIE or the external terminals SB. The conductive pillar CPIL may be a metallic pillar including metal (e.g., copper).

The molding layer MOL may be provided on the lower redistribution layer RLL, covering the die DIE. The molding layer MOL may cover a sidewall of the conductive pillar CPIL. The molding layer MOL may have a sidewall aligned with that of the lower redistribution layer RLL. The molding layer MOL may expose a top surface CPILa of the conductive pillar CPIL. For example, the molding layer MOL may include a dielectric polymer, such as an epoxy-based molding compound.

The under pad layer NPL may be provided on the top surface CPILa of the conductive pillar CPIL and on a top surface MOLa of the molding layer MOL. The under pad layer NPL may include at least one under pad NPD and a first dielectric film PID1. The under pad NPD may be provided on the top surface CPILa of the conductive pillar CPIL. The under pad NPD may be directly connected to the conductive pillar CPIL.

The under pad NPD may include a seed pad SDP and a conductive pad CD on the seed pad SDP. The seed pad SDP may include a conductive seed material. The conductive seed material may include one or more of copper, titanium, and any alloy thereof. The first dielectric film PID1 may be provided on the top surface MOLa of the molding layer MOL.

The under pad layer NPL may expose a top surface of the under pad NPD. The under pad NPD may not protrude upwardly beyond the under pad layer NPL. For example, the top surface of the under pad NPD may be located at a level the same as that of a top surface of the first dielectric film PID1. In this description, the term “level” may indicate a vertical level and may be measured in the second direction D2, or in a direction perpendicular to the top surface of the under pad NPD or to the top surface of the first dielectric film PID1. The phrase “certain components are the same in terms of level” may include an allowable tolerance possibly occurring during fabrication process.

Referring to FIG. 4, the top surface MOLa of the molding layer MOL may not be flat when viewed in an enlarged scale. For example, the top surface MOLa of the molding layer MOL may have a total thickness variation TV of about 1 micrometer to about 10 micrometers. The total thickness variation TV on the top surface MOLa of the molding layer MOL may depend on a particle size of molding compound. The first dielectric film PID1 may be provided on the top surface MOLa of the molding layer MOL. No void may be included between the molding layer MOL and the first dielectric film PID1. For example, the top surface MOLa of the molding layer MOL and a bottom surface of the first dielectric film PID1 may be in contact with each other with no gap.

The upper redistribution layer URL may be provided on the lower structure FSTL. The upper redistribution layer URL may include a back redistribution layer of the semiconductor package PKG. The upper redistribution layer URL may include a second bump layer BPL2, a first upper redistribution layer URL1, a second upper redistribution layer URL2, and a third redistribution layer URL3.

The second bump layer BPL2 may include upper bump patterns UBP. The first upper redistribution layer URL1 may include first upper redistribution patterns URP1. The second upper redistribution layer URL2 may include second upper redistribution patterns URP2. The third upper redistribution layer URL3 may include upper bonding pads URP3 and a second dielectric film PID2. The upper bonding pad URP3 may be connected through the under pad NPD to the top surface CPILa of the conductive pillar CPIL. The under pad NPD may be interposed between the upper bonding pad URP3 and the conductive pillar CPIL so that the conductive pillar CPIL is electrically connected to the upper bonding pad URP3. The second dielectric film PID2 may be provided on the first dielectric film PID1. The upper bonding pads URP3 may not protrude downwardly beyond the third upper redistribution layer URL3.

Each of the first upper redistribution pattern URP1, the second upper redistribution pattern URP2, and the upper boding pad URP3 may include a second seed pattern SP2 and a conductive pattern CP below the second seed pattern SP2. The second seed patterns SP2 may include a conductive seed material. The conductive seed material may include one or more of copper, titanium, and any alloy thereof.

The present inventive concepts are not limited to that shown, and the upper redistribution layer URL may have no limitation imposed on the number of redistribution layers and the number of redistribution patterns.

Referring to FIG. 3, among the first and second upper redistribution patterns URP1 and URP2 and the upper bonding pads URP3 of the upper redistribution layer URL, the first upper redistribution pattern URP1 is representatively illustrated. The first upper redistribution pattern URP1 may include a second line part LP2 and a second via part VP2.

The second via part VP2 may include a portion of the second seed pattern SP2 and a portion of the conductive pattern CP below the second seed pattern SP2. The second via part VP2 may be provided on the second line part LP2. The second line part LP2 may have a bottom surface LP2b in partial contact with a second dielectric layer PL2, another redistribution pattern, or an upper bonding pad. The second line part LP2 may have a top surface LP2a which is connected to a bottom surface VP2b of the second via part VP2. The second via part VP2 may be provided between the second line part LP2 and an upper bump pattern (or another redistribution pattern). The second line part LP2 may be electrically connected through the second via part VP2 to the upper bump pattern (or another redistribution pattern).

The second via part VP2 may have a second width W2. The second width W2 may refer to a length between one and opposite lateral surfaces of the second via part VP2. The second width W2 may decrease in a direction from the bottom surface VP2b toward a top surface VP2a of the second via part VP2, or in the second direction D2 (or in a direction toward the lower redistribution layer). In other words, the second width W2 may increase in a vertical direction toward the second line part LP2 from a top surface VP2a of the second via part VP2. A width at the bottom surface VP2b of the second via part VP2 may be greater than that at the top surface VP2a of the second via part VP2.

The upper bonding pads URP3 may be connected to the under pads NPD. The conductive pattern CP of the upper bonding pad URP3 may be directly connected to the conductive pad CD of the under pad NPD.

The upper bump patterns UBP may be electrically connected to the die DIE or the external terminals SB through the first upper redistribution patterns URP1, the second upper redistribution patterns URP2, the upper bonding pads URP3, the under pads NPD, and the conductive pillars CPIL. As the first and second upper redistribution patterns URP1 and URP2 are provided, the upper bump patterns UBP may be disposed offset from the conductive pillars CPIL.

The upper redistribution layer URL may include a plurality of second dielectric layers PL2. The second dielectric layers PL2 may include an organic material, such as a photo-imagable dielectric (PID) material. The photo-imagable dielectric material may be a polymer. The photo-imagable dielectric material may include, for example, one or more of photosensitive polyimide, polybenzoxazole, phenolic polymers, and benzocyclobutene polymers. The number of stacked second dielectric layers PL2 may be variously changed. The plurality of second dielectric layers PL2 may include the same material. No distinct interface may be provided between neighboring second dielectric layers PL2.

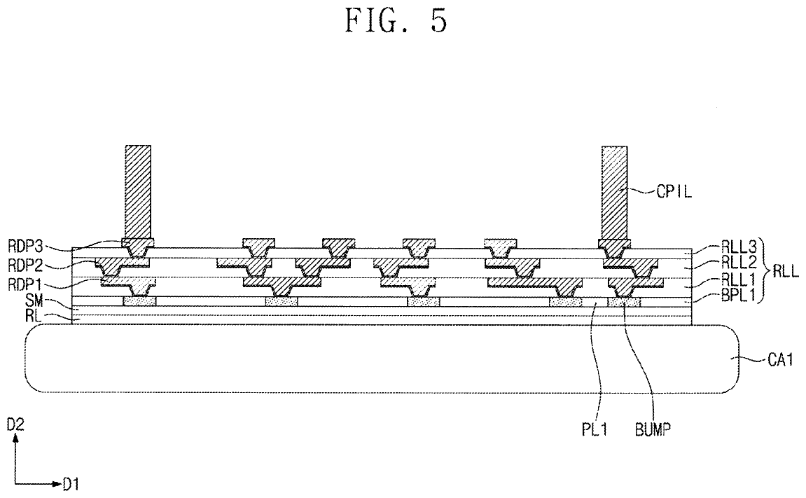

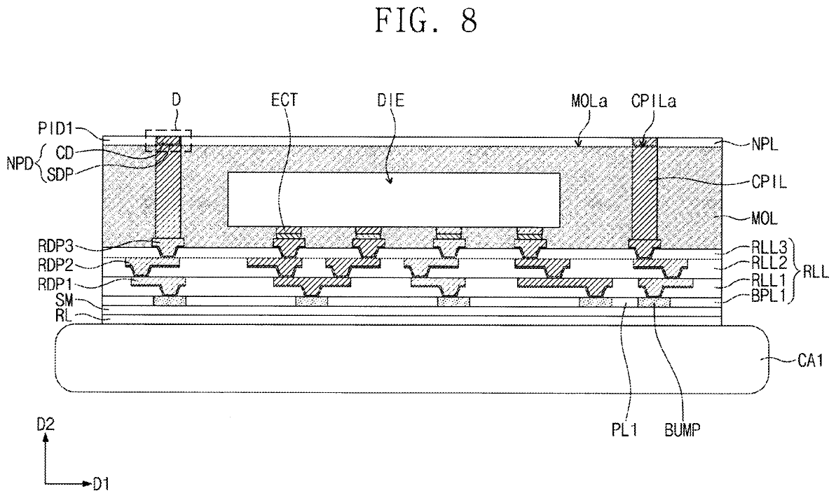

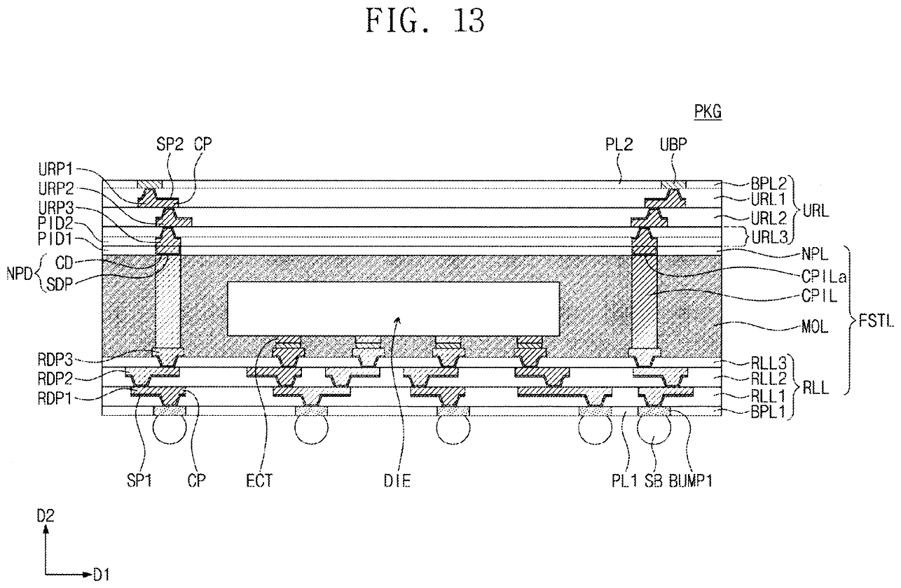

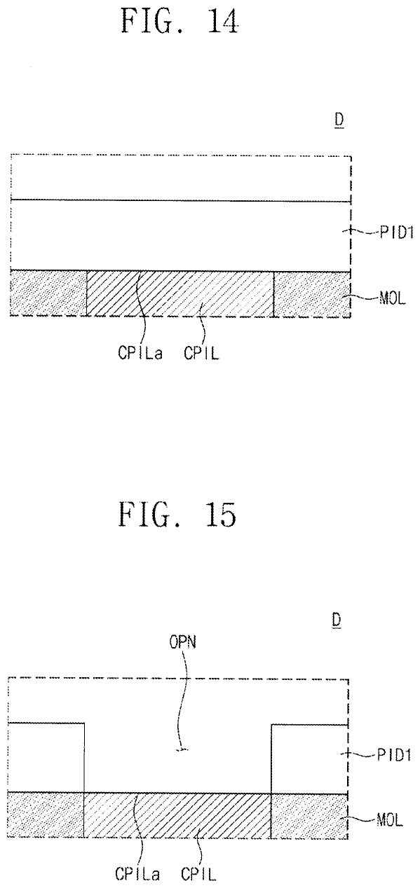

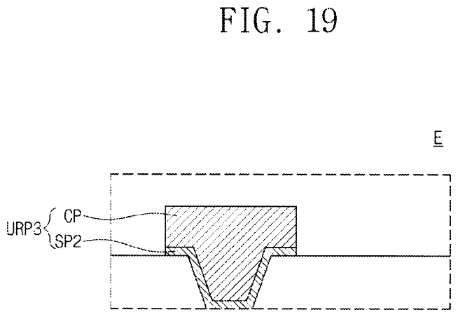

FIGS. 5 to 13 illustrate cross-sectional views showing a method of fabricating a semiconductor package according to some example embodiments of the present inventive concepts. FIGS. 14 to 18 illustrate cross-sectional views showing in detail the formation of section D of FIG. 8. FIGS. 19 to 21 illustrate cross-sectional views showing in detail the formation of section E of FIG. 10. The following will now describe in detail a method of fabricating a semiconductor package according to some example embodiments of the present inventive concepts.

FIGS. 5 to 8 show the formation of a lower structure.

Referring to FIG. 5, a first carrier CA1 may be sequentially provided thereon with an adhesion layer RL, a release layer SM, and a lower redistribution layer RLL. A conductive pillar CPIL may be formed on the lower redistribution layer RLL. As discussed below, the adhesion layer RL may be removed by laser irradiation.

The formation of the lower redistribution layer RLL may include sequentially forming on the first carrier CA1 a first bump layer BPL1, a first lower redistribution layer RLL1, a second lower redistribution layer RLL2, and a third lower redistribution layer RLL3.

The first bump layer BPL1 may include lower bump patterns BUMP. The first lower redistribution layer RLL1 may include first lower redistribution patterns RDP1. The second lower redistribution layer RLL2 may include second lower redistribution patterns RDP2. The third lower redistribution layer RLL3 may include lower bonding pads RDP3. The present inventive concepts are not limited to that shown in figures, and the lower redistribution layer RLL may have no limitation imposed on the number of redistribution layers and the number of redistribution patterns.

The formation of the lower bump patterns BUMP, the first lower redistribution patterns RDP1, the second lower redistribution patterns RDP2, and the lower bonding pads RDP3 may include forming a first dielectric layer PL1 on a layer thereunder and then performing a photoresist process.

For example, the formation of each of the first, second, and third lower redistribution layers RLL1, RLL2, and RLL3 may include forming a first dielectric layer, forming an opening in the first dielectric layer, forming a seed layer in the opening, and performing an electroplating process to form a conductive layer on the seed layer (e.g., plating the seed layer with metal to form a conductive layer on the seed layer). Thus, each of the first, second, and third lower redistribution layers RLL1, RLL2, and RLL3 may include a plurality of redistribution patterns that are formed spaced apart from each other.

At least one conductive pillar CPIL may be formed on the lower redistribution layer RLL. The conductive pillar CPIL may be provided on an edge region of the lower redistribution layer RLL. The conductive pillar CPIL may be connected to the lower bonding pad RDP3 that corresponds thereto. For example, the conductive pillar CPIL may be electrically connected to the lower redistribution layer RLL.

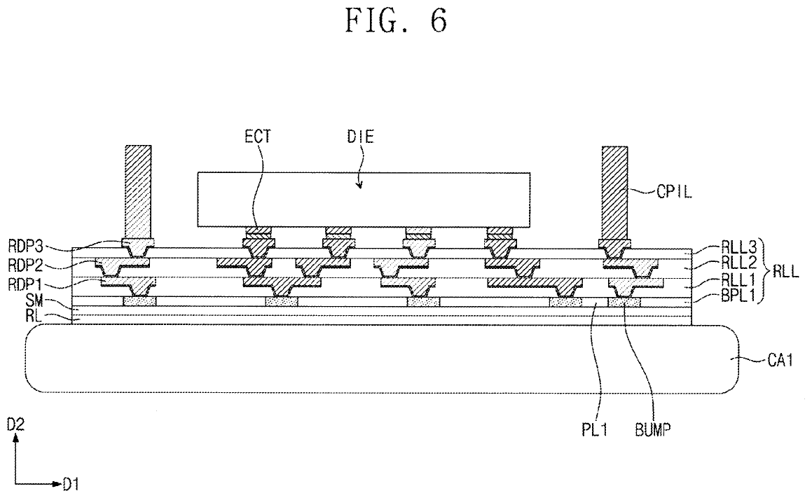

FIG. 6 shows the mounting of a die on a redistribution layer. Referring to FIG. 6, a die DIE may be mounted on the lower redistribution layer RLL. The die DIE may be a semiconductor chip.

The die DIE may have a top surface and a bottom surface that are opposite to each other. The bottom surface of the die DIE may be directed toward the lower redistribution layer RLL and may be an active surface. The top surface of the die DIE may be an inactive surface. For example, the die DIE may include a semiconductor substrate, integrated circuits, and external connection members ECT. The integrated circuits may be adjacent to the bottom surface of the die DIE. The external connection members ECT may be coupled to the integrated circuits. The phrase “a certain component is electrically connected to the die DIE” may mean “a certain component is electrically connected through the external connection members ECT of the die DIE to the integrated circuits of the die DIE.”

Differently from that shown, an additional die (or a semiconductor chip) may be mounted on the lower redistribution layer RLL.

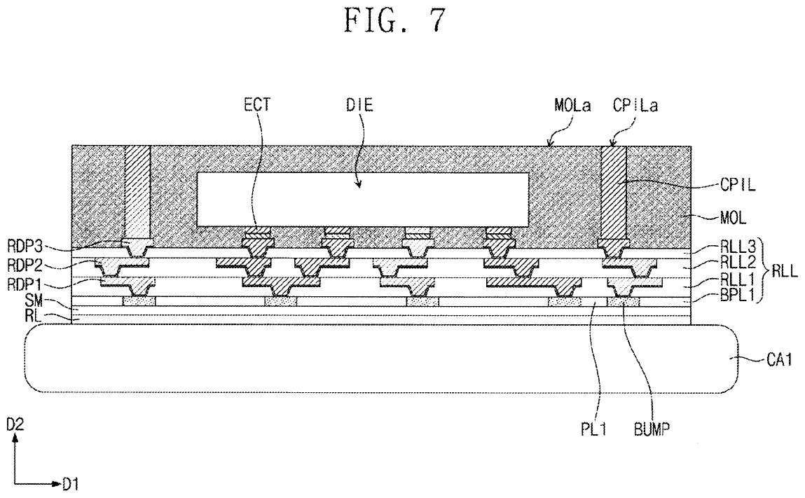

Referring to FIG. 7, a molding layer MOL may be formed on the lower redistribution layer RLL, covering the die DIE. The molding layer MOL may cover a sidewall of the conductive pillar CPIL. The molding layer MOL may have a sidewall aligned with that of the redistribution layer RLL.

The molding layer MOL may include a dielectric polymer, such as an epoxy-based molding compound. For example, the formation of the molding layer MOL may include liquefying a molding compound by applying heat and pressure to the molding compound, and then curing the liquefied molding compound. Afterwards, a grinding process may further be performed to grind the cured molding compound. As a result of the grinding process, the molding layer MOL may have a top surface MOLa at a level the same as or lower than that of a top surface CPILa of the conductive pillar CPIL. The grinding process may cause the molding layer MOL to have a rough surface on the top surface MOLa. For example, the top surface MOLa of the molding layer MOL may have a total thickness variation TV of about 1 micrometer to about 10 micrometers. The molding layer MOL may expose the top surface CPILa of the conductive pillar CPIL.

FIG. 8 shows the formation of an under pad layer on a molding layer and a conductive pillar. Referring to FIG. 8, an under pad layer NPL may be formed on the top surface MOLa of the molding layer MOL and on the top surface CPILa of the conductive pillar CPIL. The under pad layer NPL may include at least one under pad NPD and a first dielectric film PID1. The under pad NPD may be formed on the top surface CPILa of the conductive pillar CPIL.

The formation of the under pad NPD will be discussed in detail with reference to FIGS. 14 to 18A.

Referring to FIGS. 8 and 14, the first dielectric film PID1 may be provided on the molding layer MOL and the conductive pillar CPIL.

Referring to FIGS. 8 and 15, an opening OPN may be formed in the first dielectric film PID1 so as to expose the top surface CPILa of the conductive pillar CPIL. The formation of the opening OPN may include using a photoresist to etch the first dielectric film PID1.

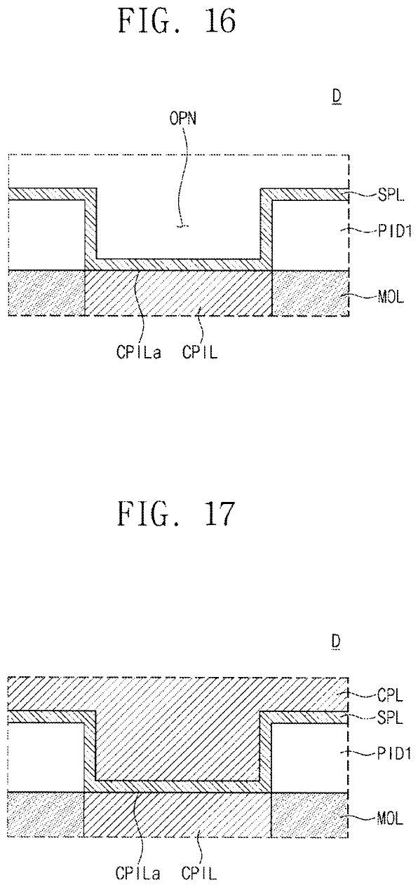

Referring to FIGS. 8 and 16, a seed pad layer SPL may be provided in the opening OPN and on the first dielectric film PID1. The seed pad layer SPL may include a conductive seed material. The conductive seed material may include one or more of copper, titanium, and any alloy thereof.

Referring to FIGS. 8 and 17, a conductive layer CPL may be formed on the seed pad layer SPL. The formation of the conductive layer CPL may include electroplating process a conductive material.

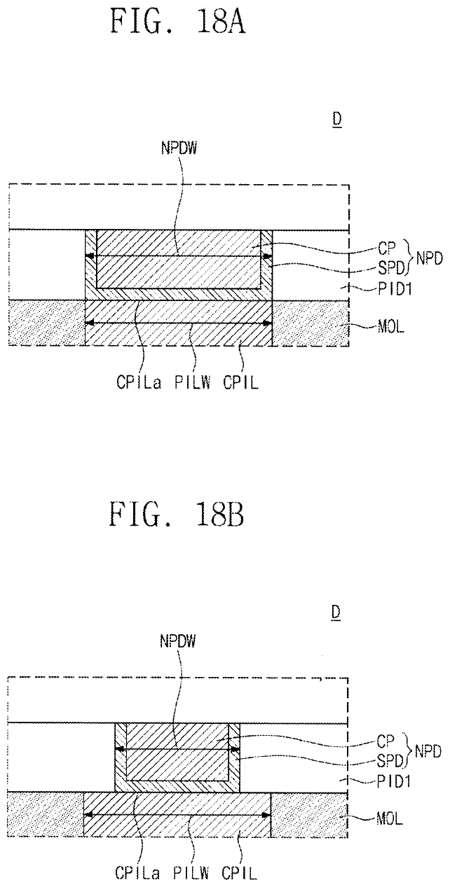

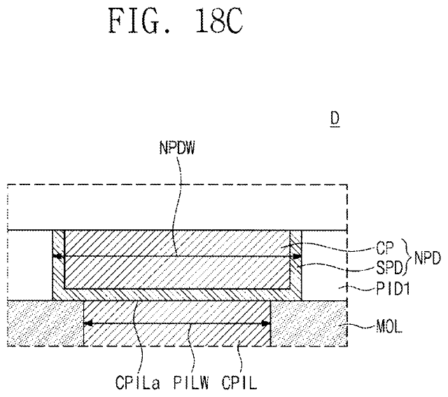

Referring to FIGS. 8 and 18A, a polishing process may be performed to remove a portion of the conductive layer CPL and a portion of the seed pad layer SPL. The polishing process may include a chemical mechanical polishing (CMP) process. The polishing process may provide seed pads SDP and conductive pads CP that are separated from other seed pads SDP and other conductive pads CP. The polishing process may cause the under pad NPD (e.g., the conductive pattern CP) to have a top surface at a level the same as that of a top surface of the first dielectric film PID1.

FIGS. 18B and 18C show other example embodiments of the under pad depicted in FIG. 18A according to the present inventive concepts.

Referring to FIGS. 18A to 18C, the under pad NPD may have an under-pad width NPDW. The under-pad width NPDW may refer to a length between one and opposite lateral surfaces of the under pad NPD. The conductive pillar CPIL may have a conductive-pillar width PILW. The conductive-pillar width PILW may refer to a length between one and opposite lateral surfaces of the conductive pillar CPIL.

According to some example embodiments of the present inventive concepts, the under-pad width NPDW may be the same as the conductive-pillar width PILW (see FIG. 18A).

According to some example embodiments of the present inventive concepts, the under-pad width NPDW may be less than the conductive-pillar width PILW (see FIG. 18B).

According to some example embodiments of the present inventive concepts, the under-pad width NPDW may be greater than the conductive-pillar width PILW (see FIG. 18C).

When an upper redistribution layer is bonded directly after grinding a molding layer, roughness at a top surface of the molding layer may form a void between the molding layer and the upper redistribution layer. Thus, there may be a problem of the occurrence of undulation on the upper redistribution layer bonded to the top surface of the molding layer. In contrast, according to some example embodiments of the present inventive concepts discussed above, as a under pad layer including a first dielectric layer is provided. Thus, no gap may be present between the under pad layer (e.g., the first dielectric film therein) and the top surface of the molding layer. Moreover, as the under pad layer has a flat top surface (in other words, as the top surface of the lower structure is flat), the problem of undulation on the upper redistribution layer may be reduced or solved.

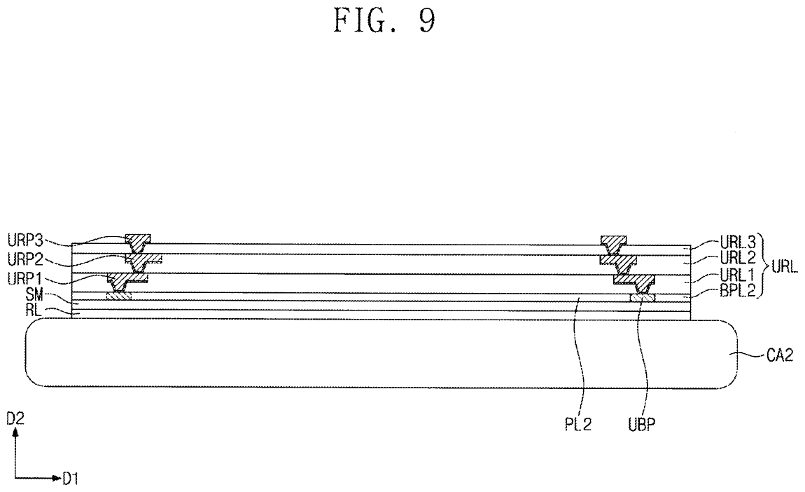

FIGS. 9 and 10 show the formation of an upper redistribution layer.

FIG. 9 shows the formation of a second bump layer and first to third upper redistribution layers. FIG. 10 shows the formation of a second dielectric layer on a third lower redistribution layer.

Referring to FIGS. 9 and 10, there may be provided a second carrier CA2 and an upper redistribution layer URL on the second carrier CA2.

The upper redistribution layer URL may include a second bump layer BPL2, a first upper redistribution layer URL1, a second upper redistribution layer URL2, and a third redistribution layer URL3. The second bump layer BPL2 may include upper bump patterns UBP. The first upper redistribution layer URL1 may include first upper redistribution patterns URP1. The second upper redistribution layer URL2 may include second upper redistribution patterns URP2. The third upper redistribution layer URL3 may include upper bonding pads URP3 and a second dielectric film PID2. The present inventive concepts are not limited thereto, and the upper redistribution layer URL may have no limitation imposed on the number of redistribution layers and the number of redistribution patterns.

The formation of each of the upper bump patterns UBP, the first upper redistribution patterns URP1, the second upper redistribution patterns URP2, and the upper bonding pads URP3 may include forming a second dielectric layer PL2 on a layer thereunder and then performing a photoresist process.

The upper bump patterns UBP, the first upper redistribution patterns URP1, the second upper redistribution patterns URP2, and the upper bonding pads URP3 may be formed by the same method as that used for forming the redistribution layer RLL of FIG. 5.

The third upper redistribution layer URL3 may further include a second dielectric film PID2. With further reference to FIGS. 19 to 21, the following will discuss in detail the formation of the second dielectric film PID2.

Referring to FIGS. 10 and 19, the formation of the third upper redistribution layer URL3 may include forming the upper bonding pad URP3 on the second dielectric layer PL2. The upper bonding pad URP3 may include a second seed pattern SP2 and a conductive pattern CP on the second seed pattern SP2. The upper bonding pad URP3 may have a shape that protrudes onto the second dielectric layer PL2.

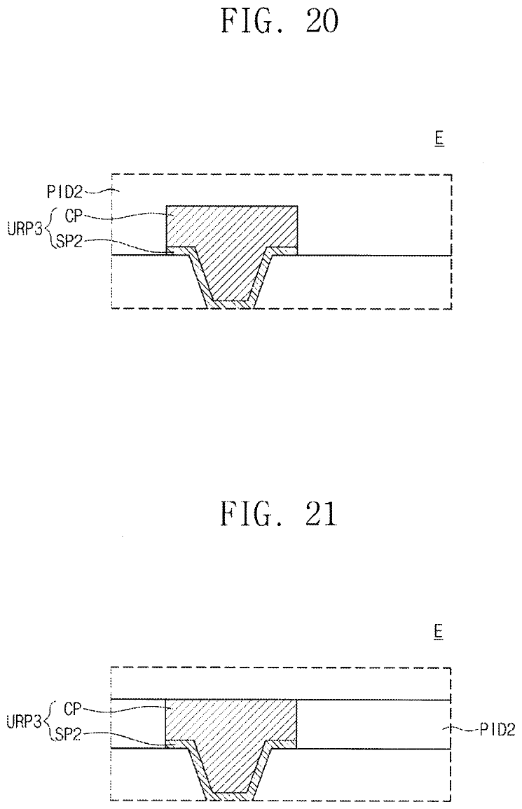

Referring to FIGS. 10 and 20, the second dielectric film PID2 may be formed on the second dielectric layer PL2 and the upper bonding pad URP3. The second dielectric film PID2 may cover the second dielectric layer PL2 and the upper bonding pad URP3.

Referring to FIGS. 10 and 21, the second dielectric film PID2 may be polished to cause the second dielectric film PID2 to have a top surface at a level the same as that of a top surface of the upper bonding pad URP3.

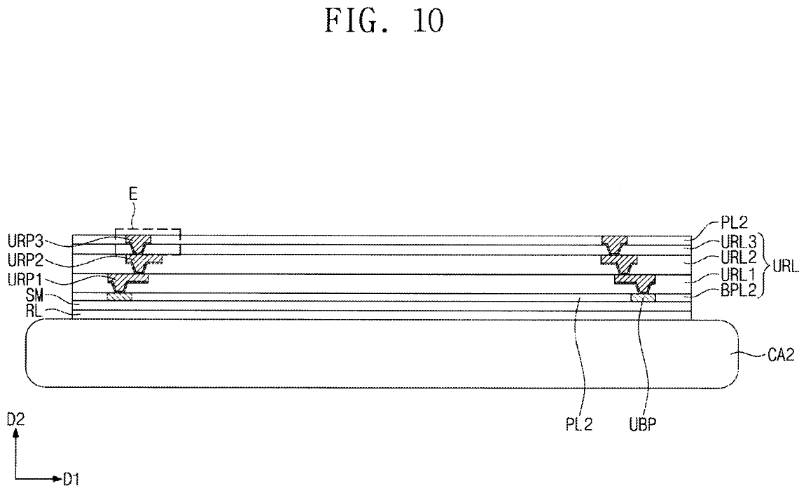

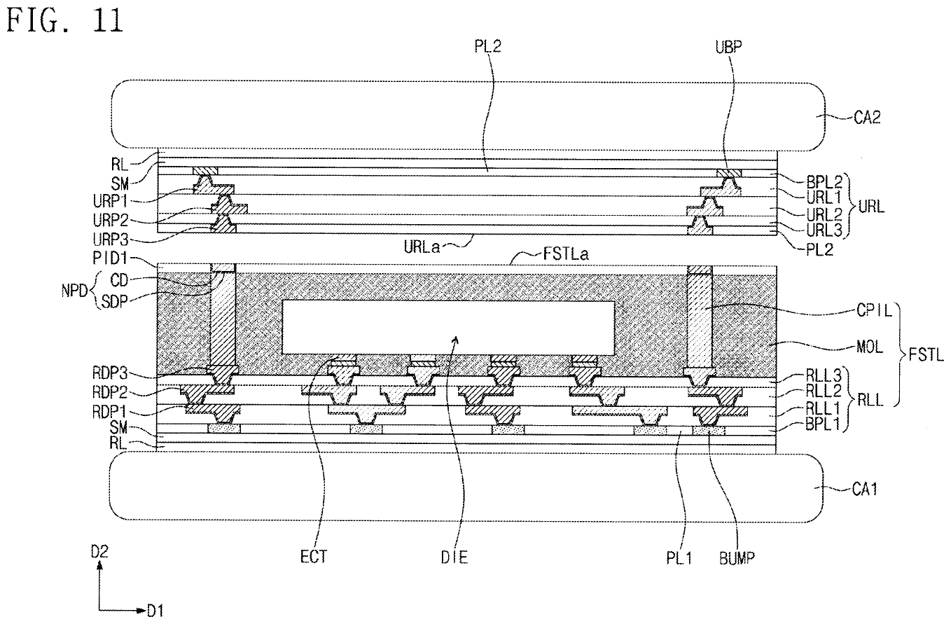

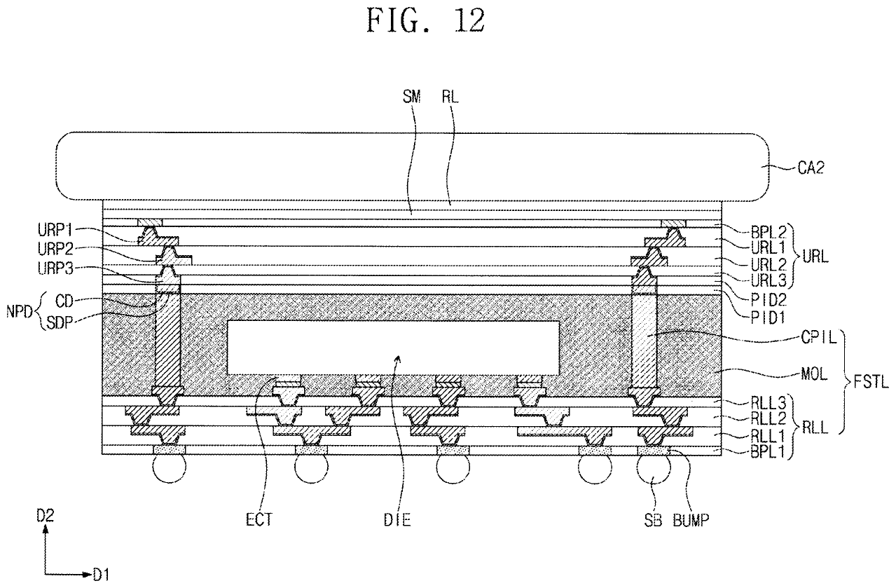

FIGS. 11 to 13 illustrate cross-sectional views showing the bonding between a lower structure and an upper redistribution layer. FIG. 11 shows that a first carrier and a second carrier are aligned to face each other. FIG. 12 shows the separation a first carrier and the bonding of an external terminal after the bonding of a lower structure to an upper redistribution layer. FIG. 13 shows the separation of a second carrier.

Referring to FIGS. 11 to 13, the second carrier CA2 may be turned upside down to cause a top surface URLa of the upper redistribution layer URL to face a top surface FSTLa of the lower structure FSTL. The upper redistribution layer URL and the lower structure FSTL may be aligned with each other to allow the upper bonding pads URP3 of the upper redistribution layer URL to vertically overlap corresponding under pads NPD of the lower structure FSTL.

Referring to FIG. 12, the upper bonding pads URP3 may be coupled to corresponding ones of the under pads NPD. A bonding process may be performed such that the first dielectric film PID1 may be bonded to the second dielectric film PID2. Therefore, the upper redistribution layer URL may be attached to the lower structure FSTL. The bonding process between the upper bonding pads URP3 and the under pads NPD may include a high-speed surface activated boding process that uses Ar plasma.

After completion of the bonding process, a laser may be irradiated in a second direction D2 to the first carrier CA1 such that the adhesion layer RL may be removed. Therefore, the first carrier CA1 may be separated from the lower structure FSTL. Afterwards, a process may be performed to remove the release layer SM. A plurality of external terminals SB may be provided below corresponding ones of the lower bump patterns BUMP. For example, the external terminal SB may be a solder ball.

Referring to FIG. 13, the second carrier CA2 may be separated from the upper redistribution layer URL. The separation of the second carrier CA2 may be performed by the same method used for separating the first carrier CAL After the separation of the second carrier CA2, a process may be performed to remove the release layer SM.

In a fabrication method (referred to hereinafter as a conventional fabrication method) including a step of forming a front redistribution layer on a carrier substrate, a step of mounting a die, a step of forming a molding layer, and a step of forming a back redistribution layer on the molding layer are sequentially performed, the carrier may be damaged because a thermal process is repetitively executed in the step of forming the back redistribution layer. In contrast, according to some example embodiments of the present inventive concepts, as the front redistribution layer and the back redistribution layer are formed separately from each other and then are bonded to each other, the carrier may be mitigated or prevented from being damaged. In addition, the carrier may increase in lifespan.

In the conventional fabrication method, even when failure only occurs in forming the back redistribution layer, there is a problem in that it is needed to discard the front redistribution layer and a die bonded thereto together. However, according to some example embodiments of the present inventive concepts, because the back redistribution layer is formed individually, when failure occurs in the step of forming the back redistribution layer, only the failed back redistribution layer may need to be discarded. Thus, compared to the conventional fabrication method, some example embodiments of the present inventive concepts may increase in process yield.

In the conventional fabrication method, an adhesive is desired to bond the carrier to the back redistribution layer. In contrast, according to some example embodiments of the present inventive concepts, a second carrier may be provided such that no separate adhesive may be desired. Thus, compared to the conventional fabrication method, some example embodiments of the present inventive concepts may have an advantage in terms of cost.

In the conventional fabrication method, as the formation of the molding layer is followed by the formation of the back redistribution layer, a temperature condition is needed to cure a molding member. In other words, a molding member is chosen to include a material curable under a temperature condition associated with the formation of the back redistribution layer. However, according to some example embodiments of the present inventive concepts, as the formation of the back redistribution layer is performed individually, a selection range of molding members may increase.

In the conventional fabrication method, heat is applied when a dielectric layer is formed on each redistribution layer, and thus when a thermal process is repeatedly performed after the formation of the dielectric layer, there is a problem of a reduction in reliability of a semiconductor package. In contrast, according to some example embodiments of the present inventive concepts, as the front redistribution layer and the back redistribution layer are formed individually from each other, there may be a reduction in repetition time of a thermal process applied to each redistribution layer and an increase in reliability of a semiconductor package.

According to some example embodiments of the present inventive concepts, the formation of a molding layer may be followed by the formation of a first dielectric film on the molding layer. It may be possible to solve a problem of the occurrence of undulation on the back redistribution layer when the back redistribution layer is stacked on a top surface of the molding layer after grinding the molding layer.

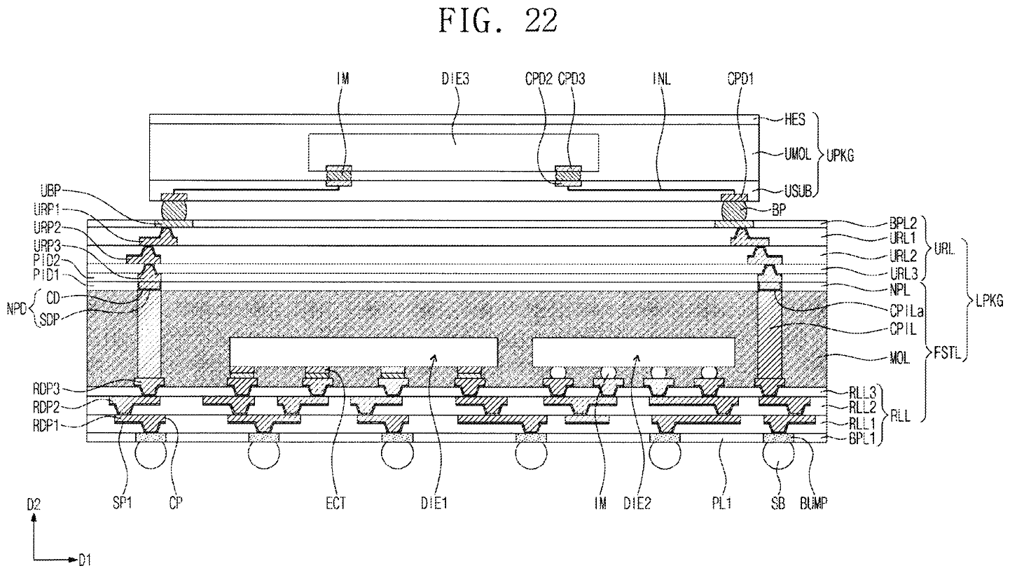

FIG. 22 illustrates a cross-sectional view showing a semiconductor package according to some example embodiments of the present inventive concepts.

Referring to FIG. 22, a semiconductor package according to some example embodiments may include a lower semiconductor package LPKG and an upper semiconductor package UPKG. The lower semiconductor package LPKG may include a lower structure FSTL, external terminals SB, and an upper redistribution layer URL. The lower structure FSTL may include a lower redistribution layer RLL, connection terminals IM, a first die DIE1, a second die DIE2, an under pad layer NPL, and conductive pillars CPIL.

The lower redistribution layer RLL may include a first bump layer BPL1, a first lower redistribution layer RLL1, a second lower redistribution layer RLL2, and a third lower redistribution layer RLL3 that are sequentially stacked. The first lower redistribution layer RLL1 may include first lower redistribution patterns RDP1. The second lower redistribution layer RLL2 may include second lower redistribution patterns RDP2. The third lower redistribution layer RLL3 may include lower bonding pads RDP3. Each of the lower bonding pads RDP3 may have an upper portion that protrudes upwardly beyond the third redistribution layer RLL3. Each of the first lower redistribution pattern RDP1, the second lower redistribution pattern RDP2, and the lower bonding pad RDP3 may include a first seed pattern SP1 and a conductive pattern CP on the first seed pattern SP1. The first seed patterns SP1 may include a conductive seed material. The conductive seed material may include one or more of copper, titanium, and any alloy thereof.

A plurality of lower bump patterns BUMP may be provided below the first lower redistribution layer RLL1. The lower bump patterns BUMP may be connected to corresponding ones of the first lower redistribution patterns RDP1. A plurality of external terminals SB may be provided below corresponding ones of the lower bump patterns BUMP. The lower bump pattern BUMP may lie between and connect the external terminal SB and the first lower redistribution pattern RDP1. For example, the external terminal SB may be a solder ball. The external terminal SB may include, for example, tin, bismuth, lead, silver, or any alloy thereof.

The first die DIE1 and the second die DIE2 may be provided on the lower redistribution layer RLL. The first die DIE1 and the second die DIE2 may be mounted side by side in a first direction D1 on the lower redistribution layer RLL.

The first die DIE1 may be a semiconductor chip of a different type from that of the second die DIE2. For example, the first die DIE1 may include one of a logic chip, a memory chip, and a power management chip, and the second die DIE2 may include another of a logic chip, a memory chip, and a power management chip.

Differently from that shown, an additional die (or a semiconductor chip) may be mounted on the lower redistribution layer RLL.

A plurality of external connection members ECT of the first die DIE1 may be disposed on corresponding ones of the lower bonding pads RDP3 of the lower redistribution layer RLL. As the external connection members ECT are connected to corresponding one of the lower bonding pads RDP3, such that the first die DIE1 and the lower redistribution layer RLL may be electrically connected to each other.

A plurality of connection terminals IM each may be interposed between the second die DIE2 and a corresponding one of lower bonding pads RDP3 of the lower redistribution layer RLL. The second die DIE2 and the lower redistribution layer RLL may be electrically connected to each other through the connection terminals IM. For example, the connection terminals IM may include micro-bumps.

At least one conductive pillar CPIL may be provided on the lower redistribution layer RLL. The conductive pillar CPIL may be provided on an edge region of the lower redistribution layer RLL. The conductive pillar CPIL may be horizontally spaced apart from the first die DIE1 and the second die DIE2.

The conductive pillar CPIL may be connected to the lower bonding pad RDP3 that corresponds thereto. For example, the conductive pillar CPIL may be electrically connected to the lower redistribution layer RLL. For example, the conductive pillar CPIL may be electrically connected through the lower redistribution layer RLL to the first die DIE1, the second die DIE2, or the external terminals SB. The conductive pillar CPIL may be a metallic column including metal (e.g., copper).

A molding layer MOL may be provided on the lower redistribution layer RLL, covering the first die DIE1 and the second die DIE2. The molding layer MOL may cover a sidewall of the conductive pillar CPIL. The molding layer MOL may have a sidewall aligned with that of the lower redistribution layer RLL. The molding layer MOL may expose a top surface CPILa of the conductive pillar CPIL. For example, the molding layer MOL may include a dielectric polymer (e.g., an epoxy-based molding compound).

An under pad layer NPL may be provided on a top surface of the molding layer MOL. The under pad layer NPL may include an under pad NPD and a first dielectric film PID1. The under pad NPD may be provided on the conductive pillar CPIL. The under pad NPD may be electrically connected to the top surface CPILa of the conductive pillar CPIL. The under pad NPD may include a seed pad SDP and a conductive pad CD on the seed pad SDP. The seed pad SDP may include a conductive seed material. The conductive seed material may include one or more of copper, titanium, and any alloy thereof. The first dielectric film PID1 may be provided on the top surface of the molding layer MOL.

The under pad layer NPL may expose a top surface of the under pad NPD. The under pad NPD may not protrude upwardly beyond the under pad layer NPL. For example, the top surface of the under pad NPD may be located at a level the same as that of a top surface of the first dielectric film PID1.

The upper redistribution layer URL may be provided on the under pad NPD. The upper redistribution layer URL may include a second bump layer BPL2, a first upper redistribution layer URL1, a second upper redistribution layer URL2, and a third redistribution layer URL3.

The second bump layer BPL2 may include upper bump patterns UBP. The first upper redistribution layer URL1 may include first upper redistribution patterns URP1. The second upper redistribution layer URL2 may include second upper redistribution patterns URP2. The third upper redistribution layer URL3 may include upper bonding pads URP3 and a second dielectric layer PL2. The upper bonding pad URP3 may be electrically connected to the top surface CPILa of the conductive pillar CPIL through the under pad NPD. The second dielectric film PID2 may be provided on the first dielectric film PID1. The upper bonding pads URP3 may not protrude downwardly beyond the third upper redistribution layer URL3.

Each of the first upper redistribution pattern URP1, the second upper redistribution pattern URP2, and the upper boding pad URP3 may include a second seed pattern SP2 and a conductive pattern CP below the second seed pattern SP2.

The upper bonding pads URP3 may be connected to the under pads NPD. The conductive pattern CP of the upper bonding pad URP3 may be directly connected to the conductive pad CD of the under pad NPD.

The upper bump patterns UBP may be electrically connected to the first die DIE1, the second die DIE2, or the external terminals SB through the first upper redistribution patterns URP1, the second upper redistribution patterns URP2, the upper bonding pads URP3, the under pads NPD, and the conductive pillars CPIL. As the first and second upper redistribution patterns URP1 and URP2 are provided, the upper bump patterns UBP may be disposed offset from the conductive pillars CPIL.

The upper semiconductor package UPKG may be provided on the lower semiconductor package LPKG. For example, the upper semiconductor package UPKG may be mounted on the upper redistribution layer URL. The upper semiconductor package UPKG may include an upper substrate USUB, a third die DIE3, and an upper molding layer UMOL. For example, the upper substrate USUB may be a printed circuit board. For another example, the upper substrate USUB may be a redistribution substrate such as the lower redistribution layer RLL of the lower semiconductor package LPKG.

A first conductive pad CPD1 and a second conductive pad CPD2 may be disposed on a bottom surface and a top surface of the upper substrate USUB, respectively. The upper substrate USUB may have therein a wire line INL coupled to the first conductive pad CPD1 and the second conductive pad CPD2. The wire line INL is schematically illustrated and may be variously changed in shape and arrangement. The first conductive pad CPD1, the second conductive pad CPD2, and the wire line INL may include a conductive material, such as metal.

The third die DIE3 may be disposed on the upper substrate USUB. The third die DIE3 may include an integrated circuit (not shown), and the integrated circuit may include a memory circuit, a logic circuit, or a combination thereof. The third die DIE3 may be a semiconductor chip of a different type from that of the first die DIE1 and that of the second die DIE2. For example, the third die DIE3 may be a memory chip. The second conductive pad CPD2 and the third die DIE3 may have therebetween a connection terminal IM that connects the upper substrate USUB to the third die DIE3. The third die DIE3 may be electrically connected to the first conductive pad CPD1 through the connection terminal IM and the wire line INL.

The upper substrate USUB may be provided thereon with the upper molding layer UMOL that covers the third die DIE3. The upper molding layer UMOL may include a dielectric polymer, such as an epoxy-based polymer.

The upper semiconductor package UPKG may further include a thermal radiation structure HES. The thermal radiation structure HES may include a heat sink, a heat slug, or a thermal interface material layer. For example, the thermal radiation structure HES may include metal. The thermal radiation structure HES may be disposed on a top surface of the upper molding layer UMOL. The thermal radiation structure HES may further extend onto a sidewall of the upper molding layer UMOL.

A plurality of upper external terminals BP may be provided between the lower semiconductor package LPKG and the upper semiconductor package UPKG. The upper external terminal BP may be interposed between the upper bump pattern UBP and the first conductive pad CPD1, thereby connecting the lower semiconductor package LPKG to the upper semiconductor package UPKG. For example, the upper semiconductor package UPKG may be electrically connected through the upper external terminals BP to the first die DIE1, the second die DIE2, or the external terminals SB. An electrical connection with the upper semiconductor package UPKG may mean an electrical connection with an integrated circuit in the third die DIE3. The upper external terminal BP may include a solder, a bump, or a combination thereof. The upper external terminal BP may include a solder material.

According to some example embodiments of the present inventive concepts, a lower structure and an upper redistribution layer may be formed individually from each other to fabricate a semiconductor package. Therefore, a method of fabricating a semiconductor package according to some example embodiments of the present inventive concepts may reduce process time, compared to a case where the lower structure is formed and then the upper redistribution layer is directly formed on the lower structure.

Although the present inventive concepts have been described in connection with some example embodiments of the present inventive concepts illustrated in the accompanying drawings, it will be understood by one of ordinary skill in the art that variations in form and detail may be made therein without departing from the spirit and essential features of the present inventive concepts. The above disclosed example embodiments should thus be considered illustrative and not restrictive.

What is claimed is:

1. A semiconductor package, comprising:
a lower structure; and
an upper redistribution layer on the lower structure,
wherein the lower structure includes,
a first bump layer including a bump pattern,
a lower redistribution layer including a plurality of first redistribution layers stacked on the first bump layer,
a semiconductor chip on the lower redistribution layer,
a molding layer on the lower redistribution layer and covering the semiconductor chip,
a conductive pillar on the lower redistribution layer and penetrating the molding layer, and
an under pad layer on the molding layer and including an under pad, wherein the upper redistribution layer includes,
a second bump layer including an upper bump pattern, and
a plurality of second redistribution layers stacked between the second bump layer and the under pad layer,
wherein each of the plurality of first redistribution layers includes a lower redistribution pattern,
the lower redistribution pattern includes a first line part and a first via part, and
a width of the first via part increases in a first vertical direction toward the first line part from a bottom surface of the first via part, and
wherein each of the plurality of second redistribution layers includes an upper redistribution pattern,
the upper redistribution pattern includes a second line part and the second via part,
the second via part is on the second line part, and
a width of the second via part increases in a second vertical direction toward the second line part from a top surface of the second via part.

2. The semiconductor package of claim 1, wherein the lower redistribution pattern includes:
a first seed pattern; and
a first conductive pattern on the first seed pattern.

3. The semiconductor package of claim 2, wherein the upper redistribution pattern includes:
a second conductive pattern; and
a second seed pattern on the second conductive pattern.

4. The semiconductor package of claim 1, wherein
the under pad layer further includes a first dielectric layer,
a top surface of the under pad is at a same level as a top surface of the first dielectric layer, and
a top surface of the lower structure is flat.

5. The semiconductor package of claim 4, wherein a gap is absent between the molding layer and the first dielectric layer.

6. The semiconductor package of claim 1, wherein a top surface of the molding layer has a thickness variation in a range of 1 micrometer to 10 micrometers.

7. The semiconductor package of claim 1, wherein
the upper redistribution layer further includes a plurality of upper bonding pads and a second dielectric layer,
the second dielectric layer is between a lowermost one of the second redistribution layers and the under pad layer, and
the upper bonding pads and the second dielectric layer are on a top surface of the under pad layer.

8. The semiconductor package of claim 7, wherein
bottom surfaces of the upper bonding pads are at a same level as a bottom surface of the second dielectric layer, and
a bottom surface of the upper redistribution layer is flat.

9. The semiconductor package of claim 1, further comprising:
an external terminal attached to the bump pattern on a bottom surface of the lower structure.

10. A method of fabricating a semiconductor package, the method comprising:
forming a lower structure on a first carrier, the forming the lower structure including,
forming on the first carrier a first bump layer that includes a bump pattern,
forming a lower redistribution layer on the first bump layer,
forming on the lower redistribution layer a conductive pillar that extends vertically, and
mounting a semiconductor chip on the lower redistribution layer;
forming on the lower redistribution layer a molding layer, the molding layer covering the semiconductor chip and the conductive pillar and exposing a top surface of the conductive pillar;
forming on the molding layer an under pad layer that includes an under pad in contact with the top surface of the conductive pillar;
forming an upper redistribution layer on a second carrier, the upper redistribution layer including an upper bonding pad at an uppermost position of the upper redistribution layer;
bonding the lower structure and the upper redistribution layer to connect the under pad and the upper bonding pad to each other; and
removing the first carrier and the second carrier.

11. The method of claim 10, wherein forming the under pad layer includes:
forming a third dielectric layer on the molding layer and the conductive pillar;
etching the third dielectric layer to form an opening in the third dielectric layer to expose at least a portion of the top surface of the conductive pillar;
forming a seed pad layer in the opening and on the third dielectric layer;
plating the seed pad layer with metal to form a conductive pattern layer; and
polishing the conductive pattern layer and the seed pad layer to expose a top surface of the third dielectric layer.

12. The method of claim 10, wherein the forming the upper redistribution layer includes forming a second dielectric layer on the second carrier.

13. The method of claim 12, wherein the forming the second dielectric layer includes:
forming the second dielectric layer to cover the upper bonding pad; and
polishing the second dielectric layer to expose a top surface of the upper bonding pad such that the second dielectric layer and the upper bonding pad to be at a same level and the upper redistribution layer to have a flat top surface.

14. The method of claim 10, wherein the bonding the lower structure and the upper redistribution layer includes performing a high-speed surface activated boding process.

15. The method of claim 10, further comprising:
attaching an external terminal to the bump pattern of the lower structure.

16. The method of claim 10, wherein
the lower redistribution layer includes a lower redistribution pattern,
the lower redistribution pattern includes a first line part and a first via part, and
a width of the first via part increases in a vertical direction toward the first line part from a bottom surface of the first via part.

17. The method of claim 10, wherein
the upper redistribution layer includes an upper redistribution pattern,
the upper redistribution pattern includes a first line part and the first via part, and
a width of the first via part increases in a vertical direction toward the first line part from a top surface of the first via part after the bonding.

18. The method of claim 16, wherein the lower redistribution pattern includes:
a first seed pattern; and
a first conductive pattern on the first seed pattern.

19. The method of claim 17, wherein the upper redistribution pattern includes:
a second seed pattern; and
a second conductive pattern on the second seed pattern.

20. The method of claim 10, wherein the forming the lower structure is performed individually from forming the upper redistribution layer.
